(19) United States
(12) Patent Application Publication
(10) Pub. No.: US 2007/0262468 A1
(43) Pub. Date: Nov. 15, 2007

(54) SEMICONDUCTOR DEVICE AND METHOD OF MANUFACTURING THE SAME

(76) Inventors: Hayato Nasu, Yokohama-shi (JP); Takamasa Usui, Tokyo (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/456,278

(22) Filed: Jul. 10, 2006

(30) Foreign Application Priority Data
May 9, 2006 (JP) 2006-130339

(51) Int. Cl. H01L 23/48

(52) U.S. Cl. 257/778

(57) ABSTRACT

A semiconductor device includes a first semiconductor chip having a first pad, a bonding member having a second pad facing the first pad, and a refractory metal layer which is formed by electroless plating in direct contact with the first pad and the second pad.

### CROSS-REFERENCE TO RELATED APPLICATIONS

This application is based upon and claims the benefit of priority from prior Japanese Patent Application No. 2006-130339, filed May 9, 2006, the entire contents of which are incorporated herein by reference.

### BACKGROUND OF THE INVENTION

1. Field of the Invention

The present invention relates to a semiconductor device in which a semiconductor chip and a bonding member are connected by electroless plating and a method of manufacturing the same.

2. Description of the Related Art

In recent years, copper (Cu) interconnections and a Low-k insulating film are used in a multilayered interconnection portion to implement high-performance LSIs.

However, since a Cu interconnection is highly oxidative, it is difficult to form, directly on the Cu interconnection, a wire using, e.g., gold (Au) or aluminum (Al) or a metal interconnection such as a bump using an alloy of, e.g., lead (Pb), palladium (Pd), zinc (Sn), or silver (Ag). Conventionally, a process of forming an additional layer on the Cu interconnection of the uppermost layer and forming a pad of Al is necessary. This indicates forming an interconnection layer that is not used for a signal interconnection, resulting in an increase in LSI chip manufacturing time and cost.

An LSI chip is connected to a package in the following way. For example, a bonding method is employed in which a metal wire is activated by heat and microwave and, in this state, connected onto a pad by mechanical pressure. Alternatively, a bump formed on an LSI pad is arranged on a surface mounting package, made surface active, and annealed. In these methods, since a low dielectric constant film (Low-k film) has much lower mechanical strength (e.g., Young's modulus or a stress value to breakdown) than that of a conventional SiO₂ film serving as an insulating film, the low dielectric constant film may break due to mechanical or thermal stress in the wiring process of the LSI chip and package. As a result, the interlayer may crack or peel off, resulting in a decrease in yield and long-term reliability.

Examples of prior art reference information related to the present invention are U.S. Pat. No. 6,335,104B1 and Japanese patent No. 3478804.

### BRIEF SUMMARY OF THE INVENTION

According to a first aspect of the present invention, there is provided a semiconductor device comprising a first semiconductor chip having a first pad, a bonding member having a second pad facing the first pad, and a refractory metal layer which is formed by electroless plating in direct contact with the first pad and the second pad.

According to a second aspect of the present invention, there is provided a semiconductor device comprising a package having a first pad, a semiconductor chip which is arranged on the package and has a second pad, a refractory metal layer which is formed by electroless plating in direct contact with the second pad, and a bonding wire which connects the refractory metal layer to the first pad.

According to a third aspect of the present invention, there is provided a semiconductor device manufacturing method comprising fixing a first semiconductor chip having a first pad and a bonding member having a second pad while making the first pad and the second pad face each other, and connecting the first pad and the second pad by growing a refractory metal layer from exposed surfaces of the first pad and the second pad by electroless plating.

According to a fourth aspect of the present invention, there is provided a semiconductor device manufacturing method comprising arranging a semiconductor chip having a second pad on a package having a first pad, connecting one end of a bonding wire to the first pad and arranging other end of the bonding wire on the second pad, and growing a refractory metal layer from the second pad and the other end of the bonding wire by electroless plating.

### BRIEF DESCRIPTION OF THE SEVERAL VIEWS OF THE DRAWING

FIG. 1A is a schematic sectional view of a semiconductor device according to the first embodiment of the present invention in which an LSI chip and a package are connected;

FIG. 1B is an enlarged view of the connection portion between the LSI chip and the package in FIG. 1A;

FIG. 2 is a flowchart showing connection of an LSI and a package by using electroless plating of a refractory metal layer according to the first embodiment of the present invention;

FIGS. 3A to 3C are schematic sectional views showing steps in manufacturing the semiconductor device according to the first embodiment of the present invention;

FIG. 4 is a schematic sectional view of a semiconductor device according to the second embodiment of the present invention in which LSI chips are connected;

FIG. 5 is a schematic sectional view of a semiconductor device according to the third embodiment of the present invention in which an LSI chip and a multilayered interconnection layer are connected; and

FIG. 6 is a schematic sectional view of a semiconductor device according to the fourth embodiment of the present invention in which an LSI chip and a package are connected by a bonding wire.

### DETAILED DESCRIPTION OF THE INVENTION

The embodiments of the present invention will be described below with reference to the accompanying drawing. The same reference numerals denote the same parts throughout the drawing.

### First Embodiment

In the first embodiment, in connecting an LSI chip (semiconductor chip) and a package (bonding member) by a surface mounting method, electrical connection is ensured by growing refractory metal layers from the Cu interconnections of the LSI chip and package by electroless plating.

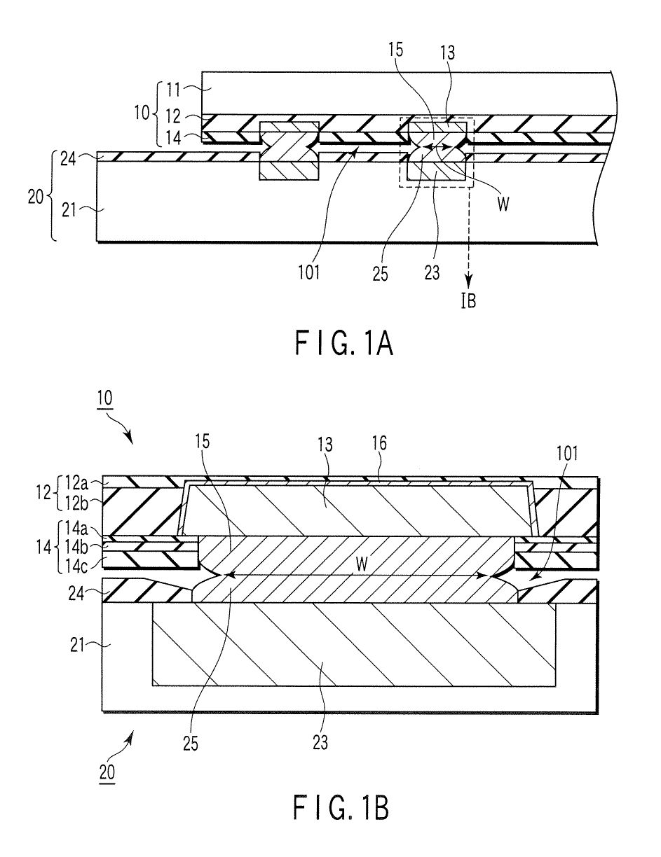

FIG. 1A is a schematic sectional view of a semiconductor device according to the first embodiment of the present invention in which an LSI chip and a package are connected. FIG. 1B is an enlarged view of the connection portion between the LSI chip and the package in FIG. 1A. The semiconductor device according to the first embodiment will be described below.

As shown in FIGS. 1A and 1B, a pad 13 as the uppermost interconnection of an LSI chip 10 is made to face a pad 23 serving as the uppermost interconnection of a package 20. The LSI chip 10 and package 20 are electrically connected through refractory metal layers 15 and 25 by electroless plating.

The pads 13 and 23 are made of, e.g., Cu. Since the refractory metal layers 15 and 25 can be formed directly on the Cu by electroless plating, no Al need be provided on the Cu, unlike the prior art. Hence, the refractory metal layers 15 and 25 are in direct contact with the pads 13 and 23. Except for the connection portion between the LSI chip 10 and the package 20, a gap 101 is formed so that a passivation film 14 of the LSI chip 10 is not in direct contact with a passivation film 24 of the package 20. The LSI chip 10 and package 20 can also be connected such that the passivation films 14 and 24 directly contact each other. If the passivation film 14 of the LSI chip 10 does not directly contact the passivation film 24 of the package 20, the bonding strength between the LSI chip 10 and the package 20 may be increased by filling the gap 101 with an underfill resin.

The structure of the connection portion between the LSI chip 10 and the package 20 will be described. Since the refractory metal layers 15 and 25 grow from both the LSI chip 10 and package 20, a width W at the intermediate portion between the refractory metal layers 15 and 25 is narrowest. When, e.g., the time of electroless plating process is adjusted, the widths of the refractory metal layers 15 and 25 can be uniformed, or the width W at the intermediate portion between the refractory metal layers 15 and 25 can be increased.

The structure of the LSI chip 10 will be described next. An interlayer dielectric film 12 is provided on a semiconductor substrate (e.g., silicon substrate) 11. The passivation film 14 is provided on the interlayer dielectric film 12. The interlayer dielectric film 12 includes an SiN film 12a and a d-TEOS (Tetra Ethyl Ortho Silicate) film 12b. The passivation film 14 includes SiN films 14a and 14c and a d-TEOS film 14b. In the interlayer dielectric film 12, the pad 13 is formed on a barrier metal film 16 made of, e.g., Ta, TaN, Ti, or TiN. The surface of the pad 13 is exposed without being covered with the passivation film 14. The refractory metal layer 15 selectively grown by electroless plating directly contacts the exposed surface of the pad 13. The pad 13 is electrically connected to, e.g., an interconnection or semiconductor element (not shown) in the LSI chip 10.

The structure of the package 20 will be described next. The passivation film 24 is provided on a package substrate 21. The pad 23 is formed in the package substrate 21. The surface of the pad 23 is exposed without being covered with the passivation film 24. The refractory metal layer 25 selectively grown by electroless plating directly contacts the exposed surface of the pad 23. The pad 13 is electrically connected to, e.g., an external terminal (not shown) of the package 20.

An example of the material of the refractory metal layers 15 and 25 is a metal containing cobalt (Co) and at least one of tungsten (W), boron (B), and phosphorus (P). Detailed examples are CoWB, CoWP, CoWPB, CoP, CoB, and CoPB. A refractory metal indicates a metal having a melting point at a temperature that cannot be used for a multilayer process and, for example, a metal having a melting point of 500° C. or more.

For example, the interlayer dielectric film 12 and passivation films 14 and 24 in the LSI chip 10 and package 20 may include a low dielectric constant film (Low-k film) or an ultra low dielectric constant film (ULow-k film). A low dielectric constant film indicates a film whose relative dielectric constant is lower than that (about 4.0 to 4.5) of a silicon oxide film formed by plasma chemical vapor deposition (CVD), i.e., a film having a relative dielectric constant of, e.g., about 2.5 to 3.8. An ultra low dielectric constant film indicates a porous film having a higher porosity than a low dielectric constant film and a relative dielectric constant of 3.0 or less. Examples of the low dielectric constant film are SiOC, organic polymer insulating film, and SiOF. Examples of the ultra low dielectric constant film are porous SiOC, porous organic polymer insulating film, and porous SiOF. The ultra low dielectric constant film is porous and therefore has a lower mechanical strength than the low dielectric constant film.

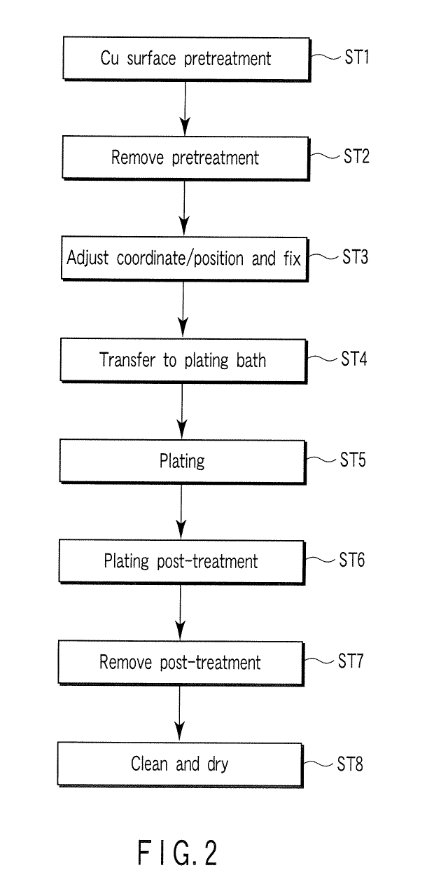

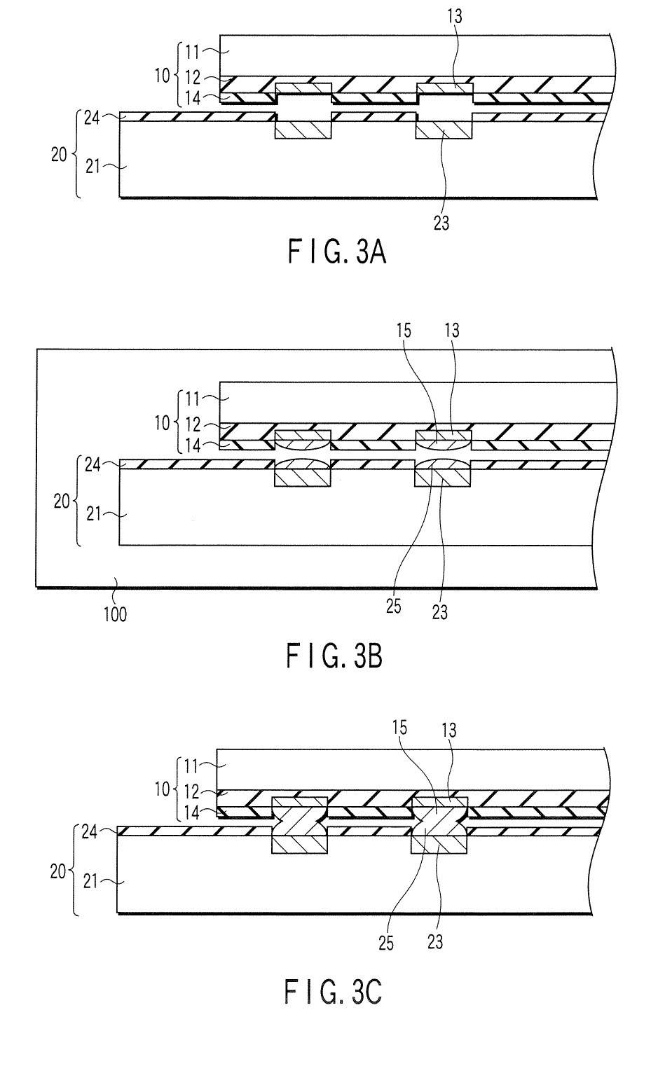

FIG. 2 is a flowchart showing connection of an LSI and a package by using electroless plating of a refractory metal layer according to the first embodiment of the present invention. FIGS. 3A to 3C are schematic sectional views showing steps in manufacturing the semiconductor device according to the first embodiment of the present invention. A semiconductor device manufacturing method according to the first embodiment will be described below.

First, as shown in FIG. 3A, the LSI chip 10 and package 20 are formed.

The LSI chip 10 is formed in, e.g., the following way. The interlayer dielectric film 12 is formed on the semiconductor substrate 11. The pad 13 made of Cu is formed in the interlayer dielectric film 12. The passivation film 14 made of, e.g., an oxide film is formed on the pad 13 and interlayer dielectric film 12. The passivation film 14 is partially removed by reactive ion etching (RIE) to expose the pad 13. After the surface pretreatment of the Cu pad 13 is executed (ST1), the pretreatment used in the process is removed (ST2).

The package 20 is formed in, e.g., the following way. The pad 23 made of Cu is formed in the package substrate 21. The passivation film 24 made of, e.g., an oxide film is formed on the pad 23 and package substrate 21. The passivation film 24 is partially removed by RIE to expose the pad 23. After the surface pretreatment of the Cu pad 23 is executed (ST1), the pretreatment used in the process is removed (ST2).

The package 20 is arranged under the LSI chip 10. The exposed surface of the pad 13 of the LSI chip 10 is directed to the side of the package 20, thereby making the pad 13 of the LSI chip 10 face the pad 23 of the package 20. In this state, position and distance adjustment is done, and the LSI chip 10 and package 20 are fixed (ST3).

As shown in FIG. 3B, the LSI chip 10 and package 20 are transferred to a plating bath 100 (ST4). Electroless plating is executed (ST5). With this process, the refractory metal layers 15 and 25 grow from the exposed surfaces of the pads 13 and 23 of the LSI chip 10 and package 20, respectively. At this time, since the refractory metal layers 15 and 25 selectively grow on the surfaces of the pads 13 and 23, interconnections do not short-circuit.

As shown in FIG. 3C, after the refractory metal layers 15 and 25 sufficiently grow and connect to each other, the LSI chip 10 and package 20 are extracted from the plating bath 100. Then, plating post-treatment is executed (ST6), and the post-treatment (e.g., residual liquid) used in this process is removed (ST7). Drying is executed (ST8), thereby completing a semiconductor device.

According to the first embodiment, the LSI chip 10 and package 20 are connected by using electroless plating of a refractory metal which can selectively grow on a metal. In this electroless plating, a refractory metal can be formed directly on Cu. Even when Cu interconnections are used as the pads 13 and 23, the conventional step of forming an Al film on a Cu interconnection can be omitted. Hence, the semiconductor device manufacturing time and cost can be reduced as compared to the prior art.

In the first embodiment, electrical connection between the LSI chip 10 and the package 20 is ensured by electroless plating growth. Hence, mechanical stress that is conventionally generated upon connecting a wire to an LSI chip can be eliminated. For this reason, even when an ultra low dielectric constant film with a low mechanical strength is used as, e.g., an interlayer dielectric film, damage to the low dielectric constant film can be suppressed. Hence, any decrease in yield and reliability caused by break of the low dielectric constant film can be suppressed. In addition, when the low dielectric constant film is used, the resistance of the LSI can be reduced, and the element can be speeded up.

The conventional surface mounting method includes an annealing step at, e.g., 180° C. to 250° C. According to the first embodiment, however, since a refractory metal grows from the pads 13 and 23 of the LSI chip 10 and package 20 by electroless plating, film formation at a low temperature (e.g., 100° C. or less) is possible. Hence, thermal stress on the LSI interconnections and interlayer dielectric film can be suppressed as compared to the prior art.

In the connection portion between an LSI chip and a package in the conventional surface mounting method, the center of a bump for connection isotropically spreads and becomes widest. According to the first embodiment, however, in the structure of the connection portion between the LSI chip 10 an the package 20, since refractory metal layers grow from both the LSI chip 10 and package 20, the width W at the intermediate portion between the refractory metal layers 15 and 25 of the connection portion can be made narrowest. Hence, the pitch of the pads 13 and 23 can be narrowed as compared to the prior art.

### Second Embodiment

In the second embodiment, an example of the interconnection structure of an LSI stack process will be described. More specifically, in the second embodiment, in connecting LSI chips (bonding members) by a surface mounting method, electrical connection is ensured by growing refractory metal layers from the Cu interconnections of both LSI chips by electroless plating.

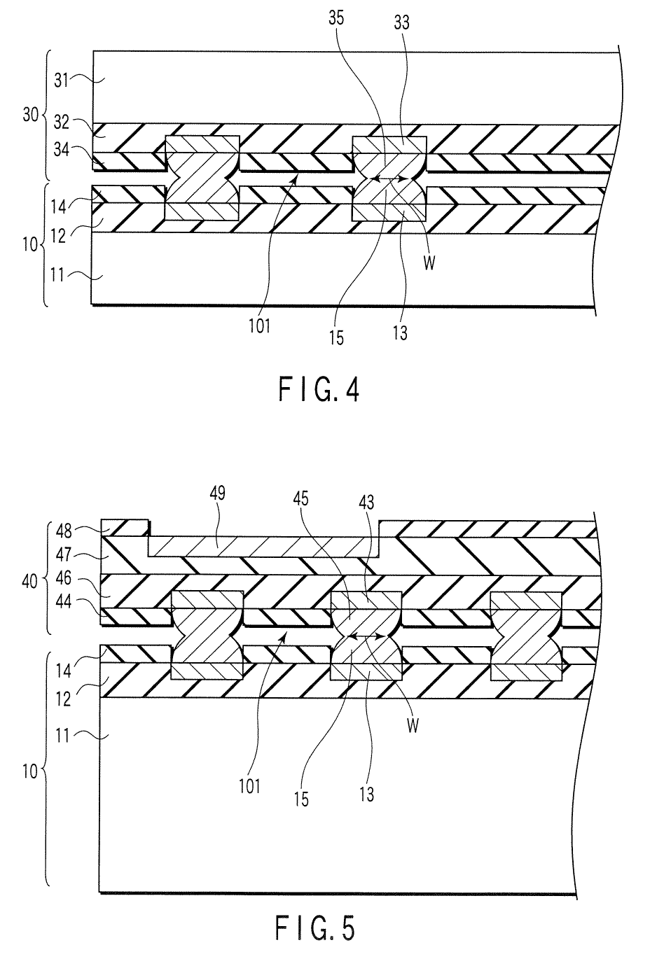

FIG. 4 is a schematic sectional view of a semiconductor device according to the second embodiment of the present invention in which LSI chips are connected. The semiconductor device according to the second embodiment will be described below.

As shown in FIG. 4, a pad 13 as the uppermost interconnection of an LSI chip 10 is made to face a pad 33 serving as the uppermost interconnection of an LSI chip 30. The LSI chips 10 and 30 are electrically connected through refractory metal layers 15 and 35 by electroless plating.

The pads 13 and 33 are made of, e.g., Cu. Since the refractory metal layers 15 and 35 can be formed directly on Cu by electroless plating, no Al need be provided on Cu, unlike the prior art. Hence, the refractory metal layers 15 and 35 are in direct contact with the pads 13 and 33. Except the connection portion between the LSI chips 10 and 30, a gap 101 is formed so that a passivation film 14 of the LSI chip 10 is not in direct contact with a passivation film 34 of the LSI chip 30. The LSI chips 10 and 30 can also be connected such that the passivation films 14 and 34 directly contact each other.

The structure of the connection portion between the LSI chips 10 and 30 will be described. Since the refractory metal layers 15 and 35 grow from both the LSI chips 10 and 30, a width W at the intermediate portion between the refractory metal layers 15 and 35 is narrowest. When, e.g., the time of electroless plating process is adjusted, the widths of the refractory metal layers 15 and 35 can be made uniform, or the width W at the intermediate portion between the refractory metal layers 15 and 35 can be increased.

The structure of the LSI chip 30 is the same as that of the LSI chip 10. However, they may have different structures. The same materials as in the first embodiment can be used for the refractory metal layers 15 and 35, interlayer dielectric films 12 and 32, and passivation films 14 and 34. In the semiconductor device manufacturing method of the second embodiment, a refractory metal is grown in a plating bath 100, thereby ensuring electrical connection between the LSI chips 10 and 30, as in the first embodiment.

According to the second embodiment, the LSI chips 10 and 30 are connected by using electroless plating of a refractory metal. Hence, the same effects as in the first embodiment can be obtained.

A conventional LSI stack employs a method of temporarily forming film packages of LSI chips and thermocompressing the surface-mounted structures or a method of connecting chips with different sizes by wire bonding. In the second embodiment, however, the mounting area can be reduced as compared to the structure that is formed by temporarily connecting a chip to a package and then stacking chips. In addition, even an LSI chip with the same size can be connected without inserting a spacer dummy LSI. A spacer dummy LSI indicates an Si chip which is inserted between an upper LSI and a lower LSI and has no function. The spacer dummy LSI aims at ensuring the space between LSIs to prevent undesirable contact between the upper LSI and the bonding wires of the lower LSI.

### Third Embodiment

In the third embodiment, an example of the interconnection structure of a multilayer bonding process will be described. More specifically, in the third embodiment, in connecting an LSI chip and a multilayered interconnection layer (bonding member), electrical connection is ensured by growing refractory metal layers from the Cu interconnections of both the LSI chip and multilayered interconnection layer by electroless plating.

FIG. 5 is a schematic sectional view of a semiconductor device according to the third embodiment of the present invention in which an LSI chip and a multilayered interconnection layer are connected. The semiconductor device according to the third embodiment will be described below.

As shown in FIG. 5, a pad 13 of an LSI chip 10 is made to face a pad 43 of a multilayered interconnection layer 40. The LSI chip 10 and multilayered interconnection layer 40 are electrically connected through refractory metal layers 15 and 45 by electroless plating.

The pads 13 and 43 are made of, e.g., Cu. Since the refractory metal layers 15 and 45 can be formed directly on Cu by electroless plating, no Al need be provided on Cu, unlike the prior art. Hence, the refractory metal layers 15 and 45 are in direct contact with the pads 13 and 43. Except the connection portion between the LSI chip 10 and the multilayered interconnection layer 40, a gap 101 is formed so that a passivation film 14 of the LSI chip 10 is not in direct contact with a passivation film 44 of the multilayered interconnection layer 40. The LSI chip 10 and multilayered interconnection layer 40 can also be connected such that the passivation films 14 and 44 directly contact each other.

The structure of the connection portion between the LSI chip 10 and the multilayered interconnection layer 40 will be described. Since the refractory metal layers 15 and 45 grow from both the LSI chip 10 and multilayered interconnection layer 40, a width W at the intermediate portion between the refractory metal layers 15 and 45 is narrowest. When, e.g., the time of electroless plating process is adjusted, the widths of the refractory metal layers 15 and 45 can be made uniform, or the width W at the intermediate portion between the refractory metal layers 15 and 45 can be increased.

The structure of the multilayered interconnection layer 40 will be described next. The pad 43 made of Cu is provided on the first surface of the multilayered interconnection layer 40. The pad 43 is provided in an interlayer dielectric film 46. The surface of the pad 43 is exposed without being covered with the passivation film 44. The refractory metal layer 45 is formed on the exposed surface of the pad 43 by electroless plating. On the other hand, a pad 49 made of Al is provided on the second surface of the multilayered interconnection layer 40. The pad 49 is provided in an interlayer dielectric film 47. The surface of the pad 49 is exposed without being covered with a passivation film 48. The pad 49 is used as, e.g., a pad for bonding.

The same materials as in the first embodiment can be used for the refractory metal layers 15 and 45, interlayer dielectric films 12, 46, and 47, and passivation films 14, 44, and 48. In the semiconductor device manufacturing method of the third embodiment, a refractory metal is grown in a plating bath 100, thereby ensuring electrical connection between the LSI chip 10 and the multilayered interconnection layer 40, as in the first embodiment.

According to the third embodiment, the LSI chip 10 and multilayered interconnection layer 40 are connected by using electroless plating of a refractory metal. Hence, the same effects as in the first embodiment can be obtained.

In the multilayer bonding process, layers using a low dielectric constant film are preferably connected by a multilayered interconnection. According to the third embodiment, a low dielectric constant film weak to mechanical stress can be used by using electroless plating of a refractory metal.

### Fourth Embodiment

In the fourth embodiment, an example of the interconnection structure by wire bonding will be described. More specifically, in the fourth embodiment, in connecting an LSI chip and a package by wire bonding, electrical connection is ensured by growing a refractory metal from the Cu interconnection of the LSI chip by electroless plating.

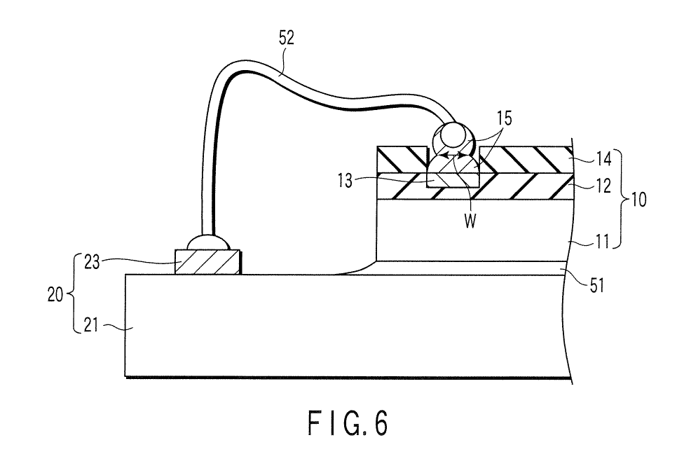

FIG. 6 is a schematic sectional view of a semiconductor device according to the fourth embodiment of the present invention in which an LSI chip and a package are connected by a bonding wire. The semiconductor device according to the fourth embodiment will be described below.

As shown in FIG. 6, an LSI chip 10 is arranged on a package 20 via a mount member 51. A pad 13 as the uppermost interconnection of the LSI chip 10 is connected to a pad 23 of the package 20 by a bonding wire 52. One end of the bonding wire 52 is connected to the pad 13 of the LSI chip 10 through refractory metal layers 15 which are selectively grown by electroless plating. The other end of the bonding wire 52 is connected directly to the pad 23 of the package 20.

The pad 13 is made of, e.g., Cu. Since the refractory metal layer can be formed directly on Cu by electroless plating, no Al need be provided on Cu, unlike the prior art. Hence, the refractory metal layer 15 is in direct contact with the pad 13.

The structure of the connection portion between the LSI chip 10 and the bonding wire 52 will be described. Since the refractory metal layers grow from both the pad 13 and bonding wire 52, a width W at the intermediate portion between the refractory metal layers 15 is narrowest. When, e.g., the time of electroless plating process is adjusted, the widths of the refractory metal layers 15 can be uniformed, or the width W at the intermediate portion between the refractory metal layers 15 can be increased.

The structure of the LSI chip 10 is the same as in the first embodiment. The same materials as in the first embodiment can be used for the refractory metal layers 15, interlayer dielectric film 12, and passivation film 14. Examples of the material of the bonding wire 52 are Au, Al, and Cu.

A semiconductor device manufacturing method according to the fourth embodiment will be described next. First, the LSI chip 10 and package 20 are formed, as in the first embodiment. The LSI chip 10 is arranged on the package 20 via the mount member 51. The bonding wire 52 is connected to the pad 23 of the package 20. Then, the other end of the bonding wire 52 is cut on the pad 13 of the LSI chip 10. The LSI chip 10 and package 20 are transferred to a plating bath. Electroless plating is executed. With this process, the refractory metal layers 15 grow from the exposed surface of the pad 13 of the LSI chip 10 and the end of the bonding wire 52 on the side of the pad 13. After the refractory metal layers 15 sufficiently grow and connect to each other, the LSI chip 10 and package 20 are extracted from the plating bath. Then, plating post-treatment is executed, and the post-treatment (e.g., residual liquid) used in this process is removed. Drying is executed, thereby completing a semiconductor device.

According to the fourth embodiment, the LSI chip 10 and package 20 are connected by using electroless plating of a refractory metal. Hence, the same effects as in the first embodiment can be obtained.

According to the fourth embodiment, mechanical stress onto the pad 13 of the LSI chip 10, which is generated in the conventional wire bonding process, can be eliminated. For this reason, damage to an ultra low dielectric constant film which is used to improve the performance of an LSI can be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first semiconductor chip having a first pad;
a bonding member having a second pad facing the first pad; and
a refractory metal layer which is formed by electroless plating in direct contact with the first pad and the second pad.

2. The device according to claim 1, wherein the bonding member comprises one of a package, a second semiconductor chip, and a multilayered interconnection layer.

3. The device according to claim 1, wherein the first pad and the second pad are substantially made of a metal mainly containing Cu.

4. The device according to claim 1, wherein the first semiconductor chip comprises a low dielectric constant film.

5. The device according to claim 1, wherein the refractory metal layer comprises a width which narrows toward an intermediate portion between the first semiconductor chip and the bonding member.

6. The device according to claim 1, wherein the refractory metal layer contains Co and at least one of W, B, and P.

7. The device according to claim 1, wherein the refractory metal layer is substantially made of one material selected from the group consisting of CoWB, CoWP, CoWPB, CoP, CoB, and CoPB.

8. The device according to claim 1, wherein a gap is formed between the first semiconductor chip and the bonding member.

9. A semiconductor device comprising:
a package having a first pad;
a semiconductor chip which is arranged on the package and has a second pad;
a refractory metal layer which is formed by electroless plating in direct contact with the second pad; and
a bonding wire which connects the refractory metal layer to the first pad.

10. The device according to claim 9, wherein the second pad is substantially made of a metal mainly containing Cu, and the semiconductor chip comprises a low dielectric constant film.

11. A semiconductor device manufacturing method comprising:
fixing a first semiconductor chip having a first pad and a bonding member having a second pad while making the first pad and the second pad face each other; and
connecting the first pad and the second pad by growing a refractory metal layer from exposed surfaces of the first pad and the second pad by electroless plating.

12. The method according to claim 11, wherein the bonding member comprises one of a package, a second semiconductor chip, and a multilayered interconnection layer.

13. The method according to claim 11, wherein the first pad and the second pad are substantially made of a metal mainly containing Cu.

14. The method according to claim 11, further comprising forming a low dielectric constant film in the first semiconductor chip.

15. The method according to claim 11, wherein the refractory metal layer is formed to become narrow toward an intermediate portion between the first semiconductor chip and the bonding member.

16. The method according to claim 11, wherein the refractory metal layer contains Co and at least one of W, B, and P.

17. The method according to claim 11, wherein the refractory metal layer is substantially made of one material selected from the group consisting of CoWB, CoWP, CoWPB, CoP, CoB, and CoPB.

18. The method according to claim 11, wherein a gap is formed between the first semiconductor chip and the bonding member.

19. A semiconductor device manufacturing method comprising:
arranging a semiconductor chip having a second pad on a package having a first pad;
connecting one end of a bonding wire to the first pad and arranging other end of the bonding wire on the second pad; and
growing a refractory metal layer from the second pad and the other end of the bonding wire by electroless plating.

20. The method according to claim 19, wherein the second pad is substantially made of a metal mainly containing Cu, and the semiconductor chip has a low dielectric constant film.
